(19) United States
(12) Patent Application Publication
(10) Pub. No.: US 2020/0019477 A1
(43) Pub. Date: Jan. 16, 2020

(54) DIVERSE REDUNDANT PROCESSING MODULES FOR ERROR DETECTION

(71) Applicant: QUALCOMM Incorporated, San Diego, CA (US)

(72) Inventors: Palkesh JAIN, Bangalore (IN); Rahul GULATI, San Diego, CA (US)

(21) Appl. No.: 16/031,813

(22) Filed: Jul. 10, 2018

(51) Int. Cl. G06F 11/16; G01R 31/317; G06F 1/10; G06F 11/18

(52) U.S. Cl. CPC G06F 11/1645; G06F 11/184; G06F 1/10; G01R 31/31703

(57) ABSTRACT

In one embodiment, a system has an integrated circuit (IC) device, the IC device includes a first processing unit having a first functional block that has a diversifiable sub-circuit and a result output, a second processing unit having a second functional block substantially identical to the first functional block that includes a corresponding diversifiable sub-circuit and a corresponding result output. The IC device includes a comparator adapted to compare the result output of the first functional block to the result output of the second functional block. The diversifiable sub-circuit of the first functional block operates using a first set of operating parameters. The diversifiable sub-circuit of the second functional block operates using a second set of operating parameters different from the first set of operating parameters.

### BACKGROUND

Integrated circuit (IC) devices process vast amounts of input data to provide output data. Occasionally, an IC device may experience a processing error. Sometimes, errors are caused by faulty design, in which case these errors may be considered systematic errors. Sometimes, processing errors have random causes, in which case these errors may be considered random errors. Random processing errors may be caused by, for example, device aging, power delivery fluctuations, process variations in the manufacture of the device, cosmic-rays, and other environmental phenomena. These random causes can, for example, affect the temporal propagation of signals such that the signals fail to timely arrive at a component, thereby causing the component to provide an erroneous output.

For many applications, occasional random errors are tolerable. For some applications, however—such as, for example, safety-critical applications—random errors need to be avoided as completely as possible. Examples of safety critical applications include, for example, advanced driver-assistance systems (ADAS), which may need to comply with safety standards such as ISO 26262 for the functional safety of electrical components, including ADAS, in automobiles.

One conventional strategy for avoiding random errors is to capture random errors by having multiple redundant processors, which have the same circuit design, simultaneously perform the same computational tasks on the same inputs and then their outputs are compared. The multiple processors are typically separate substantially identical cores of a system on chip (SoC) device. If the compared outputs match, then the comparator provides a pass output indicating no error. If the compared outputs do not match, then the comparator provides a no pass output, indicating an error.

If the compared outputs do not match, then the likely culprit is a random error since the tasks and processors are designed to be identical. The corresponding computation may then be discarded as unreliable and the computation started anew. However, in a multi-processor device, such as a SoC, where all of the processors are manufactured together and co-located on a shared substrate, all of the processors can simultaneously suffer from the same random error, which can lead the comparator to determine that the outputs—because they match—are all correct when, in fact, they are all incorrect. For example, an increase in temperature may cause a plurality of processors to have similar timing faults leading to a plurality of erroneous outputs, which do, however, match each other, thereby resulting in an incorrect determination that the outputs are error-free. Reducing the likelihood of false negatives would make for safer products.

### SUMMARY

The following presents a simplified summary of one or more embodiments to provide a basic understanding of such embodiments. This summary is not an extensive overview of all contemplated embodiments, and is intended to neither identify key critical elements of any embodiment nor delineate the scope of any or all embodiments. The summary's sole purpose is to present some concepts of one or more embodiments in a simplified form as a prelude to the more detailed description that is presented later.

In one embodiment, a system comprises an integrated circuit (IC) device. The IC device comprises a first functional block comprising a diversifiable sub-circuit and adapted to output a result, a second functional block substantially identical to the first functional block, comprising a corresponding diversifiable sub-circuit and adapted to output a corresponding result, and a comparator adapted to compare the result output of the first functional block to the result output of the second functional block. The diversifiable sub-circuit of the first functional block operates using a first set of operating parameters. The diversifiable sub-circuit of the second functional block operates using a second set of operating parameters different from the first set of operating parameters.

Another embodiment is a method for an integrated circuit (IC) device comprising a first functional block comprising a diversifiable sub-circuit and a result output, a second functional block substantially identical to the first functional block, including a corresponding diversifiable sub-circuit and a corresponding result output, and a comparator adapted to compare the result output of the first functional block to the result output of the second functional block. The method comprises operating the diversifiable sub-circuit of the first functional block using a first set of operating parameters and operating the diversifiable sub-circuit of the second functional block using a second set of operating parameters different from the first set of operating parameters.

### BRIEF DESCRIPTION OF THE DRAWINGS

The disclosed embodiments will hereinafter be described in conjunction with the appended drawings, provided to illustrate and not to limit the disclosed embodiments, wherein like designations denote like elements, and in which:

FIG. 1 is a simplified schematic diagram of a system in accordance with one embodiment of the disclosure;

FIG. 2 is a simplified schematic diagram of a system in accordance with another embodiment of the disclosure;

FIG. 3 is a simplified schematic diagram of a system in accordance with yet another embodiment of the disclosure;

FIG. 4 is a simplified schematic diagram of an exemplary embodiment of a CDN of FIG. 3;

FIG. 5 is a simplified schematic diagram of a system in accordance with an alternative embodiment of the disclosure; and

FIG. 6 is a simplified schematic diagram of a system in accordance with yet another embodiment of the disclosure.

### DETAILED DESCRIPTION

Various embodiments are now described with reference to the drawings. In the following description, for purposes of explanation, specific details are set forth to provide a thorough understanding of one or more embodiments. It may be evident, however, that such embodiment(s) may be practiced without these specific details. Additionally, the term “component” as used herein may be one of the parts that make up a system, may be hardware, firmware, and/or software stored on a computer-readable medium, and may be divided into other components.

The following description provides examples and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described and various steps may be added, omitted, or combined. Also, features described with respect to some examples may be combined in other examples. Note that, for ease of reference and increased clarity, only one instance of multiple substantially identical elements may be individually labeled in the figures.

As used herein, the term “exemplary” means “serving as an example, instance, or illustration.” Any example described as “exemplary” is not necessarily to be construed as preferred or advantageous over other examples. Use of the terms “in one example,” “an example,” “in one embodiment,” and/or “an embodiment” in this specification does not necessarily refer to the same example and/or embodiment. Furthermore, a particular feature and/or structure can be combined with one or more other features and/or structures. Moreover, at least a portion of the apparatus described hereby can be configured to perform at least a portion of a method described hereby.

It should be noted that the terms “connected,” “coupled,” and any variant thereof, mean any connection or coupling between elements, either direct or indirect, and can encompass a presence of an intermediate element between two elements that are “connected” or “coupled” together via the intermediate element. Coupling and connection between the elements can be physical, logical, or a combination thereof. Elements can be “connected” or “coupled” together, for example, by using one or more wires, cables, printed electrical connections, electromagnetic energy, and the like. The electromagnetic energy can have a wavelength at a radio frequency, a microwave frequency, a visible optical frequency, an invisible optical frequency, and the like, as practicable. These are several non-limiting and non-exhaustive examples.

A reference using a designation such as “first,” “second,” and so forth does not limit either the quantity or the order of those elements. Rather, these designations are used as a convenient method of distinguishing between two or more elements or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” or “one or more of A, B, or C” or “at least one of the group consisting of A, B, and C” used in the description or the claims can be interpreted as “A or B or C or any combination of these elements.” For example, this terminology can include A, or B, or C, or (A and B), or (A and C), or (B and C), or (A and B and C), or 2A, or 2B, or 2C, and so on.

The terminology used herein is for the purpose of describing particular examples only and is not intended to be limiting. As used herein, the singular forms “a,” “an,” and “the” include the plural forms as well, unless the context clearly indicates otherwise. Further, the terms “comprises,” “comprising,” “includes,” and “including,” specify a presence of a feature, a step, a block, an operation, an element, a component, and the like, but do not necessarily preclude a presence or an addition of another feature, step, block, operation, element, component, and the like.

In at least one example, the provided apparatuses can be a part of, and/or coupled to, an electronic device such as, but not limited to, at least one of a mobile device, a navigation device (e.g., a global positioning system receiver), a wireless device, a media player, a camcorder, an automobile, a watercraft, an aircraft, a spacecraft, and any other suitable vessel or vehicle.

The term “mobile device” can describe, and is not limited to, at least one of a mobile phone, a mobile communication device, a pager, a personal digital assistant, a personal information manager, a personal data assistant, a mobile hand-held computer, a portable computer, a tablet computer, a wireless device, a wireless modem, a computer-equipped vehicle, other types of portable or mobile electronic devices and that may have communication capabilities (e.g., wireless, cellular, infrared, short-range radio, etc.).

In some embodiments, functional diversity is intentionally introduced among sets of operating parameters of a plurality of corresponding identically designed corresponding functional blocks of a plurality of processors. Specifically, corresponding diversifiable sub-circuits of the processors are provided different sets of operating parameters. This increases the likelihood that an error-introducing change in, for example, environmental, process, voltage, or timing parameters will affect one of the plurality of processors before affecting the other processors of the plurality. This increases the likelihood that if corresponding processing units experience a similar failure, then they experience and express the failure at different times, thereby making detection of the failure more likely.

In some embodiments, the functional diversity is introduced through the diversifiable sub-circuit of the power delivery network (PDN). In some embodiments, the functional diversity is introduced through the diversifiable sub-circuit of the clock delivery network (CDN). In some embodiments, the functional diversity is introduced though both the PDN and the CDN.

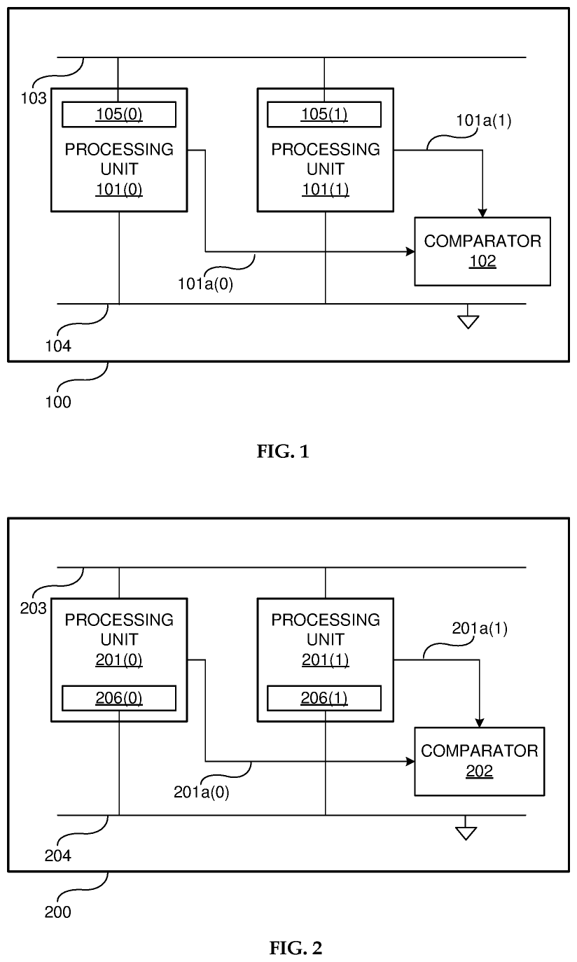

FIG. 1 is a simplified schematic diagram of system 100 in accordance with one embodiment of the disclosure. System 100 may be an SoC device. System 100 comprises a plurality of redundant processing units 101, such as processing units 101(0) and 101(1), and a comparator 102. All of the processing units 101 have the same circuit design so that given identical inputs—and barring any unique processing errors—each would produce identical outputs. In other words, the processing units 101(0) and 101(1) are substantially identical. Note that inputs to processing units include both commands and data.

A processing unit 101 may be, for example, a central processing unit (CPU), a graphics processing unit (GPU), a neural-network processing unit (NPU), or a digital signal processor (DSP). When each of the plurality of processing units 101 performs redundant processing of corresponding identical inputs (not shown), the comparator 102 compares corresponding result output signals 101a—such as, e.g., outputs 101a(0) and 101a(1)—of the processing units 101 to determine whether a unique processing error occurred in one of the processing units 101. Specifically, if the comparator 102 determines that the values received from result outputs 101a are not all identical, then the comparator provides an output indicating that at least one of the processing units 101 suffered a processing error.

The error-determination output may trigger the system 100 to consequently take responsive corrective or mitigating action. For example, the process that experienced the error may be run anew by the system 100 so as to try to get an error-free result. Note that the non-matching result output values that triggered the error determination may be discarded or may be cached for comparison to the results of the rerun. Also note that the outputs 101a may also be split for provision to other components (not shown) of the system 100. Further, note that each processing unit 101 may provide one or more additional outputs (not shown).

System 100 also comprises a power voltage rail 103 and a common (e.g., ground) voltage rail 104 for providing power to processing units 101. The power voltage rail 103 may be connected to a power supply (not shown). Each processing unit 101 includes a block header-switch (BHS) module 105, such as modules 105(0) and 105(1) of processing units 101(0) and 101(1), respectively. Note that the voltage rails 103 and 104 and the BHS modules 105 are part of the PDN of the system 100.

The BHS module 105 selectively connects and disconnects the processing unit 101 to and from the power voltage rail 103, which may be used, for example, to put the corresponding processing unit in a low-power sleep or inactive state. The BHS module 105 may, for example, comprise an array of transistors (not shown) connected between the power voltage rail 103 and the other components (e.g., logic circuits) of the processing unit 101. The ohmic resistance of each BHS module 105 may be independently controllable. This may be achieved by, for example, controlling the transistors of the array of transistors of the BHS module 105.

In one exemplary implementation, each BHS module 105 comprises ten field-effect transistors (FETs) connected in parallel between the power voltage rail 103 and the output (not shown) of the BHS module 105 to the rest of the processing unit 101. In one exemplary operational setting, BHS module 105(0) may have all ten FETs turned on and BHS module 105(1) may have eight FETs turned on and two FETs turned off. This will cause BHS module 105(1) to have a higher resistance value than BHS module 105(0), which, in turn—because of the greater voltage drop across BHS module 105(1), will cause processing unit 101(1) to have a lower core voltage value than processing unit 101(0), where the core voltage is the voltage provided by the BHS module 105 to the other components of the corresponding processing unit 101.

For example, the core voltage of processing unit 101(0) may be 1.0V while the core voltage of processing unit 101(1) may be 0.95V. The slightly lower core voltage of processing unit 101(1) will cause its circuits to operate slightly slower than the circuits of processing unit 101(0). Consequently, error-causing factors responsive to decreased processing speed may affect processing unit 101(1) before affecting processing unit 101(0) and, conversely, error-causing factors responsive to increased processing speed may affect processing unit 101(0) before affecting processing unit 101(1). As a result, the likelihood that all of the processing units 101 will be simultaneously affected by the same error is reduced.

The resistance of a BHS module 105 may, for example, be dynamically controlled during operation of the system 100 by a software or hardware controller (not shown) that selectively turns on or off the transistors of the array of transistors of the BHS module 105. Alternatively, the resistance may be set prior to boot-up using, for example, ROM, fuses, one-time programmable (OTP) memory, or other suitable non-volatile memory (NVM). Note that alternative embodiments may use different means to control the resistance of a BHS module 105.

FIG. 2 is a simplified schematic diagram of a system 200 in accordance with another embodiment of the disclosure. The system 200 is similar to system 100 of FIG. 1 and corresponding elements are similarly labeled, but with a different most-significant digit (or prefix). Similar to system 100, the system 200 comprises a plurality of processing units 201—e.g., 201(0) and 201(1)—whose corresponding outputs 201a—e.g., 201a(0) and 201a(1)—are compared by the comparator 202 to detect processing errors. The system 200 further comprises power voltage rail 203 and common voltage rail 204. System 200 uses block footer-switch (BFS) modules 206—rather than BHS modules, such as BHS modules 105 of system 100—to control the provision of power to the processing units 201. The BFS modules 206—like the BHS modules 105—may comprise an array of transistors (not shown). But unlike BHS modules 105, which connect to the power voltage line, the BFS modules 206—e.g., 206(0) and 206(1)—connect between the common voltage rail 204 and the other circuits of the processing unit 201. Similar to the above-described operation of system 100, the resistance of a BFS module 206—and, consequently, the core voltage of a processing unit 201—may be controlled by varying the number of transistors of the transistor array of the BFS module 206 that are turned on and the number that are turned off, with similar effects on the resistance of the BFS module and on the core voltage of the corresponding processing unit 201, where greater resistance of the BFS module 206 results in a lower core voltage for the corresponding processing unit 201.

In some alternative embodiments, a system may include processing units having both BHS modules and BFS modules. In this system, the core voltage of a processing unit may be set by controlling the resistances of both the processing unit's BHS module and the processing unit's BFS module.

FIG. 3 is a simplified schematic diagram of a system 300 in accordance with another embodiment of the disclosure. The system 300 comprises a plurality of redundant processing units 301—e.g., 301(0) and 301(1), a comparator 302, and a clock-generating circuit 310. Like the above-described processing units 101 of FIG. 1 and processing units 201 of FIG. 2, the processing units 301 are substantially identical so that receiving identical inputs should result in the various processing units 301 providing identical outputs 301a. The comparator 302—like the comparator 102 of FIG. 1 and the comparator 202 of FIG. 2—compares the corresponding output signals 301a—e.g., 301a(0) and 301a(1)—of the processing units 301 to determine whether a unique processing error has occurred and provide a corresponding error-detection output (not shown).

Clock generating circuit 310 outputs a clock signal 310a, which is provided to each processing unit 301. Each processing unit 301 comprises a corresponding clock-delivery network (CDN) 311—e.g., CDNs 311(0) and 311(1)—for providing the clock signal 310a to components throughout the processing unit 301. Each CDN 311 comprises individually tunable elements. When the individually tunable elements are tuned in each CDN 311 differently from the other CDNs 311, the likelihood that certain error-causing factors will affect one processing unit 301 before affecting the other processing units 301 increases. This reduces the likelihood that all of the processing units 301 will be simultaneously affected by similar random errors. This increases the overall reliability of the system 300.

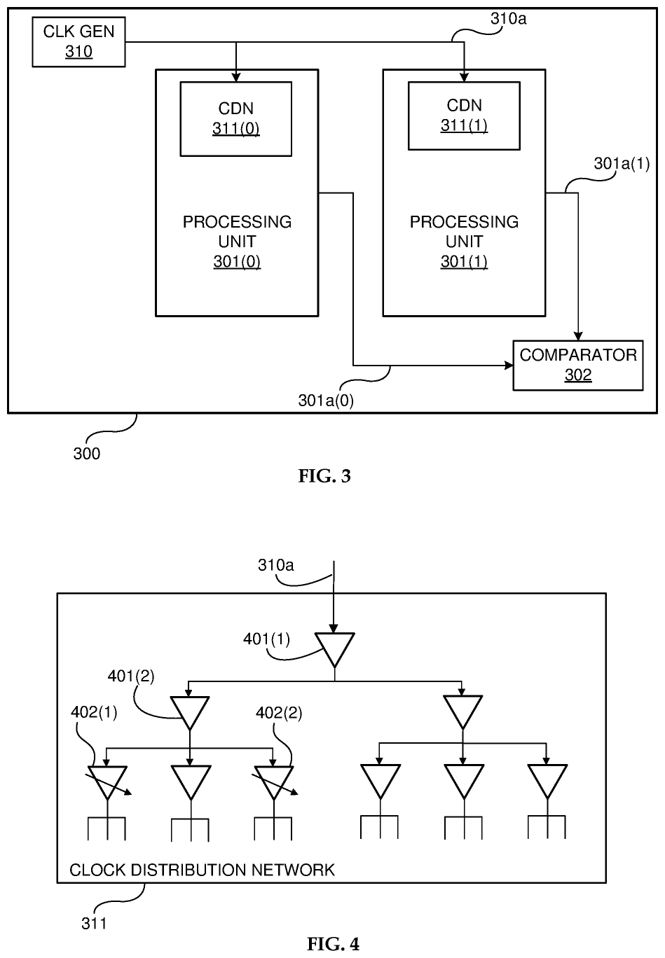

FIG. 4 is a simplified schematic diagram of an exemplary embodiment of a CDN 311 of FIG. 3. The CDN 311 comprises a plurality of delay elements, including fixed delay elements 401 and tunable delay elements 402 connected in the form of a tree. Note that delay elements may also be referred to as buffers. A root delay element 401(1) receive the clock signal 310a and provides a delayed version to a plurality of delay elements 401 or 402 that may then, in turn, provide additionally delayed clock signals to corresponding pluralities of delay elements 401 or 402. After several layers of delay elements, the delayed clock signals are received by IC components—such as, for example, flip-flops or latches (not shown)—of the processing unit 301.

In some implementations, during the circuit design of the processing units 301, critical paths in the processing units 301 are identified using suitable electronic design automation (EDA) tools. Critical paths, as used herein, refers to data-processing paths through the processing units 301 that are the first to experience failures—e.g., errors—at particular operating frequencies and/or workloads, as the supplied core voltage is reduced. In other words, the critical paths are the paths determined to be the most vulnerable to voltage droops at particular workloads/frequencies of interest. One or more of the delay elements providing a clock signal to elements along the critical path or paths may be tunable delay elements 402, while the other delay elements may be fixed delay elements 401. In the exemplary implementation of CDN 311 of FIG. 4, two tunable delay elements 402—e.g., 402(1) and 402(2)—may be used to tune the delay of the clock signal 310a to elements (not shown) along a critical path of the processing units 301.

Tuning the tunable delay elements 402 in a first processing unit 301(0) differently from a second processing unit 301(1) will increase the likelihood that certain error-inducing factors—such as a voltage droop—will affect one of the processing units 301 before affecting the other processing units 301. Consequently, this will cause a mismatch of the corresponding output signals 301a. Such a mismatch will cause the comparator 302 to output a corresponding error signal. This reduces the likelihood that an error-inducing factor will simultaneously cause similar errors in all of the processing units 301, which would produce an erroneous pass determination.

Note that tunable delay elements 402 may be more costly than fixed delay elements 401 because of the additional features offered by, and needed for, the tunable delay elements 402. Nevertheless, in some alternative embodiments, all of the delay elements of CDN 311 may be tunable delay elements.

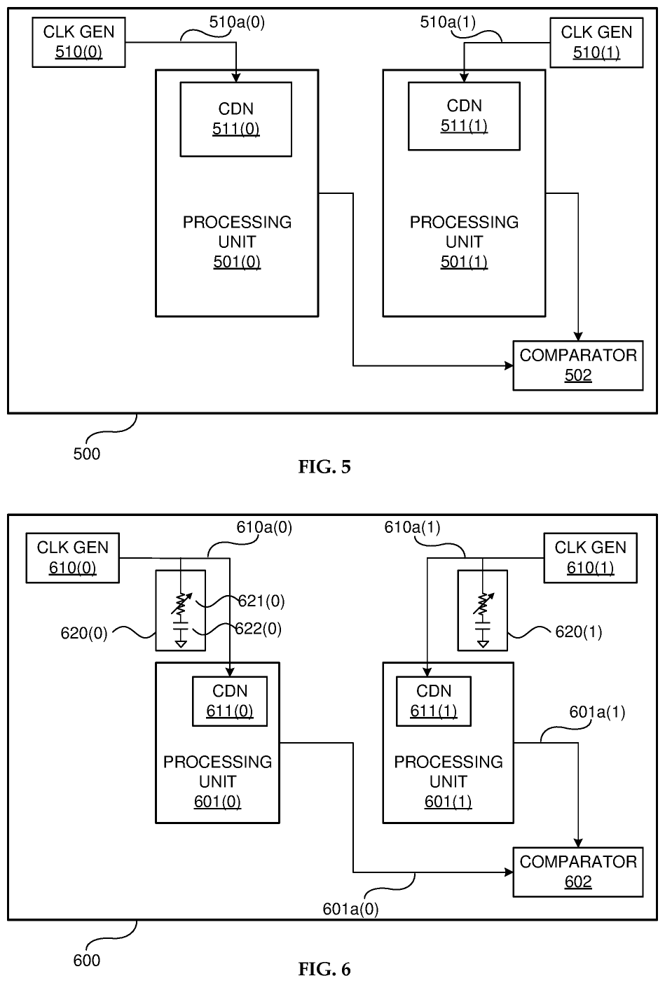

FIG. 5 is a simplified schematic diagram of a system 500 in accordance with an alternative embodiment of the disclosure. The system 500 is similar to the system 300 of FIG. 3 with similar labels, but with a different most-significant digit (or prefix), identifying similar elements. The processing units 501, CDNs 511, and comparator 502 are substantially similar to the corresponding processing units 301, CDNs 311, and comparator 302 of system 300. Unlike system 300, however, the system 500 has a an individual clock generator—510(0) and 510(1)—for each processing unit 501. The clock generators 510 have identical circuit designs and each clock generator 510 provides its own clock signal 510a—e.g., 510a(0) and 510a(1)—to the CDN 511 of the corresponding processing unit 501. The CDNs 511 comprise tunable delay elements (not shown) arranged and operated similarly to the tunable delay elements 402 of system 300. The system 500 may further include circuitry (not shown) to synchronize the plurality of clock signals 510a.

FIG. 6 is a simplified schematic diagram of a system 600 in accordance with another embodiment of the disclosure. System 600 comprises a plurality of redundant, identically designed, processing units 601—e.g., processing units 601(0) and 601(1)—whose corresponding outputs 601a—e.g., outputs 601a(0) and 601a(1), respectively, are provided to a comparator 602, which operates substantially similarly to comparators 102, 202, 302, and 502 of, respectively, systems 100, 200, 300, and 500. Each processing unit 601 receives a corresponding clock signal 610a—e.g., signals 610a(0) and 610a(1)—from a corresponding redundant, identically designed, clock-generating circuit 610—e.g., 610(0) and 610(1). The clock signals 610 are provided to corresponding CDN modules 611, which operate substantially similarly to the CDN modules 311 of FIGS. 3 and 4 and the CDN module 511 of FIG. 5. The processing units 601 and clock-generating circuits 610 share a common power supply (not shown).

The system 600 also comprises synchronization circuitry (not shown) that synchronizes the plurality of clock-generating circuits 610. The path of each clock signal 610a is connected to a filter circuit 620—e.g., circuits 620(0) and 620(1). Note that the filter circuit 620 may be considered to be part of the CDN of the corresponding processing unit Filter circuit 620 is an RC filter comprising a capacitor 622—e.g., capacitors 622(0) and 622(1)—and a tunable variable resistor 621—e.g., resistors 621(0) and 621(1). The capacitor 622 is connected between a common node and the tunable variable resistor 621. The tunable variable resistor 621 of the filter circuit 620 is connected to the path of the clock signal 610a. Note that, in some alternative embodiments, the capacitor 622 may be tunable in addition to, or instead of, the resistor 621. In some alternative embodiments, the placement of the resistor 621 and the capacitor 622 may be reversed so that the resistor 621 is connected between the common node and capacitor 622 (and the capacitor 622 is connected to the path of the clock signal 610a).

The RC constant of each filter 620 is set to a different value from the other filters 620 by, for example, adjusting the resistance of the variable resistor 621. In alternative embodiments with tunable capacitors, the RC constants may be set by, for example, adjusting the capacitance of the tunable capacitors in addition to, or instead of, the resistances of the resistors. The adjusting may be dynamically performed by a software or hardware controller (not shown), similar to the above-described tuning for other embodiments.

Having different RC constants for the filters results in having differing sensitivities to supply-voltage noise for the corresponding processing units 601. The power supply to the system 600 may be subject to variations—that is, noise—from various sources, where the various sources may affect particular corresponding frequencies more than other frequencies. A filter 620 may function to attenuate voltage-supply noise in a particular frequency range, but not in others. Accordingly, by differently turning each RC filter 620, each corresponding processing unit 601 may become sensitive to a type of supply-voltage noise different from the types to which the other processing units 601 may be sensitive. As a result, any particular type of supply-voltage noise is likely to affect one processing unit 601 before affecting the other processing units 601, which, in some cases, might not even be at all affected by the particular noise. This, in turn, reduces the likelihood that an error-inducing factor will simultaneously cause similar errors in all of the processing units 601. Consequently, the overall reliability of the system 600 is increased.

Embodiments have been described with particular exemplary numbers of components. However, the invention is not limited to the particular exemplary numbers and alternative implementations may have different numbers of components. For example, alternative implementations may have more than two processing units, each with a differently diversified PDN and/or CDN.

Embodiments of the invention have been described as comprising a plurality of processing units each having the same circuit design. It should be noted that sameness of circuit design refers to sameness of the functional blocks used for redundant-processing-unit error checking. In other words, devices with processing units having differences between circuits that are not part of the functional blocks may still fall within the scope of this disclosure. Note that a functional block may be equivalent to the processing unit that comprises the functional block. Alternatively, a functional block may be a sub-circuit of the processing unit, where the processing unit comprises additional circuitry that is not part of the functional block.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for operating an adaptive clock distribution system. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

1. A system comprising an integrated circuit (IC) device, the IC device comprising:
a first functional block comprising a diversifiable sub-circuit and adapted to output a result;
a second functional block substantially identical to the first functional block, comprising a corresponding diversifiable sub-circuit and adapted to output a corresponding result; and
a comparator adapted to compare the result output of the first functional block to the result output of the second functional block, wherein:
the diversifiable sub-circuit of the first functional block operates using a first set of operating parameters; and
the diversifiable sub-circuit of the second functional block operates using a second set of operating parameters different from the first set of operating parameters.

2. The system of claim 1, wherein:
the first and second functional blocks are adapted to receive identical inputs and process the inputs identically.

3. The system of claim 1, wherein the diversifiable sub-circuit comprises a power delivery network (PDN) for the corresponding functional block.

4. The system of claim 3, wherein:
the PDN comprises a block header-switch module;
the block header-switch module has a variable resistance; and
the first and second sets of operating parameters control the variable resistance of the corresponding block header-switch module to provide different core voltages to the first and second functional blocks.

5. The system of claim 4, wherein:
the block header-switch module comprises a plurality of transistors;
operating the diversifiable sub-circuit of the first functional block using the first set of operating parameters results in a first number of transistors of the corresponding block header-switch module being on; and
operating the diversifiable sub-circuit of the second functional block using the second set of operating parameters results in a second number of transistors of the corresponding block header-switch module, different from the first number, being on.

6. The system of claim 3, wherein:
the diversifiable sub-circuit comprises a block footer-switch module;
the block footer-switch module has a variable resistance; and
the first and second sets of operating parameters control the variable resistance of the corresponding block footer-switch module to provide different core voltages to the first and second functional blocks.

7. The system of claim 1, wherein the diversifiable sub-circuit comprises a clock delivery network (CDN) for the corresponding functional block.

8. The system of claim 7, wherein:
the CDN comprises a plurality of delay elements arranged in the form of a tree;
the plurality of delay elements comprises a set of tunable delay elements; and
the first and second operating parameters control the delays of the corresponding sets of tunable delay elements to provide different delays along selected paths of the first and second functional block.

9. The system of claim 7, wherein:
the diversifiable sub-circuit comprises:
a clock input to the corresponding functional block; and
a tunable RC filter having an RC constant and connected to the clock input; and
the first and second sets of operating parameters control the RC constant of the corresponding RC filters to have different RC constants so that the first and second functional block are sensitive to different frequencies of power-supply noise.

10. The system of claim 9, wherein the tunable RC filter comprises as least one of a tunable resistor and a tunable capacitor.

11. The system of claim 1, wherein the system is a vehicle.

12. The system of claim 1, wherein:
the device is a system on chip (SoC) device;
the SoC comprises a first processing unit and a second processing unit;
the first processing unit comprises the first functional block; and
the second processing unit comprises the second functional block.

13. A method for an integrated circuit (IC) device comprising a first functional block comprising a diversifiable sub-circuit and adapted to output a result, a second functional block substantially identical to the first functional block, comprising a corresponding diversifiable sub-circuit and adapted to output a corresponding result, and a comparator adapted to compare the result output of the first functional block to the result output of the second functional block, the method comprising:
operating the diversifiable sub-circuit of the first functional block using a first set of operating parameters; and
operating the diversifiable sub-circuit of the second functional block using a second set of operating parameters different from the first set of operating parameters.

14. The method of claim 13, wherein:
the first and second functional blocks are adapted to receive identical inputs and process the inputs identically.

15. The method of claim 13, wherein the diversifiable sub-circuit comprises a power delivery network (PDN) for the corresponding functional block.

16. The method of claim 15, wherein:
the PDN comprises a block header-switch module;
the block header-switch module has a variable resistance; and
the method comprises the first and second sets of operating parameters controlling the variable resistance of the corresponding block header-switch module to provide different core voltages to the first and second functional blocks.

17. The method of claim 16, wherein:
the block header-switch module comprises a plurality of transistors; and
the method comprises:
operating the diversifiable sub-circuit of the first functional block using the first set of operating parameters to have a first number of transistors of the corresponding block header-switch module on; and
operating the diversifiable sub-circuit of the second functional block using the second set of operating parameters to have a second number of transistors of the corresponding block header-switch module, different from the first number, on.

18. The method of claim 16, wherein:
the diversifiable sub-circuit comprises a block footer-switch module;
the block footer-switch module has a variable resistance; and
the method comprises the first and second sets of operating parameters controlling the variable resistance of the corresponding block footer-switch module to provide different core voltages to the first and second functional blocks.

19. The method of claim 13, wherein the diversifiable sub-circuit comprises a clock delivery network (CDN) of the corresponding functional block.

20. The method of claim 19, wherein:
the CDN comprises a plurality of delay elements arranged in the form of a tree;
the plurality of delay elements comprises a set of tunable delay elements; and
the method comprises the first and second operating parameters controlling the delays of the corresponding sets of tunable delay elements to provide different delays along selected paths of the first and second functional blocks.

21. The method of claim 19, wherein:
the diversifiable sub-circuit comprises:
a clock input to the corresponding functional block; and
a tunable RC filter having an RC constant and connected to the clock input; and
the method comprises the first and second sets of operating parameters controlling the RC constant of the corresponding RC filters to have different RC constants so that the first and second functional blocks are sensitive to different frequencies of power-supply noise.

22. The method of claim 21, wherein the tunable RC filter comprises as least one of a tunable resistor and a tunable capacitor.

23. The method of claim 13, wherein:
the device is a system on chip (SoC) device;
the SoC comprises a first processing unit and a second processing unit;
the first processing unit comprises the first functional block; and
the second processing unit comprises the second functional block.
